(19) United States
(12) Patent Application Publication
(10) Pub. No.: US 2004/0074769 A1
(43) Pub. Date: Apr. 22, 2004

(54) Thin film forming apparatus and thin film forming method

(75) Inventors: Taizo Morinaka, Chiba (JP); Toshihiro Suzuki, Chiba (JP); Noriaki Tani, Chiba (JP)

Correspondence Address: ARENT FOX KINTNER PLOTKIN & KAHN, PLLC, Suite 400, 1050 Connecticut Avenue, N.W., Washington, DC, 20036-5339, US

(73) Assignee: ULVAC, Inc.

(21) Appl. No.: 10/680,273

(22) Filed: Oct. 8, 2003

(30) Foreign Application Priority Data
Oct. 16, 2002 (JP) 301961/2002
Jul. 7, 2003 (JP) 271298/2003

(51) Int. Cl. C23C 14/34

(52) U.S. Cl. 204/298.07; 204/298.26; 204/298.23

(57) ABSTRACT

Raw material supplying sources, namely a target and a microwave gun are provided in a vacuum chamber such that they oppose a substrate, and a main evacuation port is disposed closer to the microwave gun between both the raw material supply sources. A control system memorizes oxygen gas flow rate under a predetermined argon gas flow rate, and sputter film formation rates comprised of three modes of high-, middle- and low-speeds, namely, high-speed metallic species film forming mode, low-speed compound species film forming mode and intermediate film forming mode depending on the oxygen gas flow rate, as reference data. At the time of film formation under a predetermined argon gas flow rate, an oxygen gas flow rate and an argon gas flow rate corresponding to the high-speed metallic species film forming mode are selected. Then, both the gas flow rates are controlled so as to maintain the ratio of both the flow rates of the selected oxygen gas and argon gas, and then, a reaction process by operating a microwave gun having an oxygen gas introduction port and an oxygen exhaust port nearby and a film forming process by operating a sputter target having an argon gas introduction port nearby are executed alternately so as to execute pulse-like film forming process.

### BACKGROUND OF THE INVENTION

1. Field of the Invention

The present invention relates to a thin film forming apparatus and a thin film forming method and more particularly to a metallic compound film forming apparatus and a thin film forming method for use in the same apparatus.

2. Description of the Related Art

Forming a metallic compound thin film (oxide film, nitride film, fluoride film or the like) quickly at a high precision using sputter method has been required in optical device field.

However, in case of forming the thin film according to the sputter method, when a target composed of such a metallic compound as metaloxide, for example, is used, its thin film deposition rate is retarded extremely unlike the case of metallic thin film formation. Thus, although the metallic compound thin film may be sometimes formed according to reactive sputter method in which reactive gas (for example, oxygen, nitrogen, fluorine gas or the like) is introduced into sputter atmosphere, when supply of the reactive gas is excessive, the sputter film forming rate may decrease remarkably.

Thus, according to a disclosed method (for example, Patent References 1-4), in order to keep a high film forming rate, first, ultra thin film composed of metal is deposited on a substrate according to the sputter method and next, plasma or active species originating from reactive gas is irradiated to this ultra thin film to convert to metallic compound thin film. Then, metallic compound film with a desired film thickness is formed by repeating several times processes of depositing ultra thin film and converting to the compound thin film.

However, a high precision control of the film thickness is difficult because in those conventional film forming apparatuses, the substrate is moved repeatedly between a sputter region and a reactive region, and another problem exists in accompanying an enlargement and complication of apparatus structure.

That is, the sputter apparatus disclosed in Patent References 1, 2 is constructed in a carousel type as indicated by a schematic sectional view of FIG. 1. Referring to FIG. 1, this apparatus 10 comprises a sputter film forming region (metallic film forming region) 11, an oxidizing region (reactive region) 12, these regions being disposed in the right and left direction in this paper and a substrate rotating mechanism 13 disposed in the center. Then, the sputter film forming region 11 comprises a target 14, a sputter cathode 15 constructed integrally therewith and a sputter gas introduction port 16 provided in the vicinity of these. The oxidizing region 12 comprises a microwave exciting plasma generator 17 and an oxygen gas introduction port 18 provided in the vicinity thereof. The substrate rotating mechanism 13 is constituted of a rotating drum 19a which rotates with a substrate 19 placed thereon.

In the sputter apparatus 10 constructed in this way, specified flow rates of argon gas and oxygen gas are introduced through the sputter gas introduction port 16 and the oxygen gas introduction port 18 into a vacuum chamber, in which a predetermined pressure condition is set up. The rotating drum 19a rotates and when the target 14 and the plasma generator 17 oppose the substrate 19, the film forming process and oxidizing process are executed repeatedly.

The sputter apparatus disclosed in Patent References 3, 4 is constructed so as to rotate the substrate as indicated by a schematic sectional view of FIG. 2. Referring to FIG. 2, the apparatus 20 comprises a sputter region (metallic film forming region) 21 and an oxidizing region (reactive film forming region) 22, these regions being disposed in the right and left direction of this paper. The metallic film forming region 21 is comprised of a target 24, a sputter cathode 25 constructed integrally therewith and a sputter gas introduction port 26 provided in the vicinity of these components. The oxidizing region 22 is comprised of the microwave exciting plasma generator 27 and the oxygen gas introduction port 28 provided in the vicinity thereof. A rotating substrate 29 held by a rotating substrate holder (not shown) is provided above the metallic film forming region 21 and the oxidizing region 22. In this apparatus 20, specified flow rates of argon gas and oxygen gas are introduced through the sputter gas introduction port 26 and the oxygen gas introduction port 28 into a vacuum chamber set to a predetermined pressure condition. The rotating substrate 29 is rotated and when the target 24 and the plasma generator 27 oppose the substrate 29, the film forming process and the oxidizing process are executed alternately.

The above-mentioned conventional apparatus adopts a system in which the substrate 19, 29 is rotated such that it goes into and out of the sputter film forming region 11, 21 in which film forming process is executed and the reactive region 12, 22 in which reactive process is executed. Because the substrate position which is an object for film formation always changes, stable and highly reliable film formation is difficult to obtain. Further, as described above, the rotating mechanism required by this apparatus configuration accompanies enlargement and complication of the configuration.

Referring to FIGS. 1, 2, the sputter film forming region 11, 21 and the reactive region 12, 22 are divided spatially by a partition wall 10a, 20a. However, it is difficult to keep the respective regions airtight from viewpoints of the structure, and therefore, when a substrate is moved between the film forming region and the reactive region, reactive atmosphere in the reactive region such as oxygen gas introduced for the reactive process is brought into the sputter film forming region. Consequently, the surface of the target may be deteriorated in its quality. That is, because there is always a fear that the film forming condition may become instable, this leads to an important cause for disturbing film formation with a stable quality.

In order to exclude an interference of residual gas brought into the film forming process in this way, it can be considered that when the reactive process ends, the supply of reactive gas is stopped and vacuum operation is carried out for a considerable time so as to remove the reactive gas efficiently. However, such a method requires a long time for process switch, and therefore, it is extremely inefficient.

Patent Reference 1: Japanese Patent Application Laid-Open No. H11-256327 (FIG. 1)

Patent Reference 2: Japanese Patent Application Laid-Open No. H03-229870 (FIG. 8)

Patent Reference 3: Japanese Patent Publication No. H08-19518 (FIG. 4)

Patent Reference 4: U.S. Pat. No. 4,420,385 (FIGS. 2, 4)

### SUMMARY OF THE INVENTION

In view of the above-described problem, an object of the present invention is to provide a thin film forming apparatus capable of forming a reliable film efficiently with a simple structure and a thin film forming method applied when the same apparatus is employed.

To achieve the above-described object, the present invention provides a thin film forming apparatus containing raw material supply sources, namely a sputter film forming source and a reactive gas supply source in a same vacuum chamber such that both the sources oppose a substrate, wherein a main evacuation port for evacuating the vacuum chamber is disposed closer to the reactive gas supply source between both the sources, the thin film forming apparatus further including a control system which executes a reaction process of operating the reactive gas supply source provided with a reactive gas introduction port and a reactive gas exhaust port and a film forming process of operating the sputter film forming source provided with a sputter gas introduction port.

As a result, a sputter gas flow path can be always established between the main evacuation port and the sputter film forming source at the time of film formation by evacuation through the main evacuation port in a vacuum chamber. Thus, the reactive gas emitted from the reactive gas source is shielded by gas curtain of the above-described sputter gas flow except those excited for a desired reaction and irradiated toward the substrate, thereby preventing the reactive gas from remaining near a sputter film forming source such as a sputter target. Therefore, even if the reactive gas is always supplied from the reactive gas supply source without stopping the supply of reactive gas emitted from the source, decrease in the film forming rate can be avoided under an appropriate condition.

Because the reactive gas source including reactive gas can be separated by the above-mentioned gas curtain, both the reaction process of operating the reactive gas source and the film forming process of operating the sputter film forming source provided with the sputter gas introduction port can be prevented from interfering to each other with the control system which controls both the processes. Thus, the necessity of moving the film forming region and the reactive region alternately by rotating the substrate is eliminated unlike the conventional apparatus.

On the other hand, when the thin film forming apparatus having the above-described structure for preventing the interference between the film forming process and the reaction process is used, it has been recognized that the film forming rate is plotted onto a rate curve comprised of three regions of high-, middle- and low-, namely, high-speed metallic film forming region, low-speed reactive film forming region and intermediate film forming region. By controlling these, highly reliable film formation can be carried out.

More specifically, this control has two types. Namely, one makes both the processes carried out alternately without any overlapping by starting any one of the reaction process and the film forming process after the other process ends. And another makes the film forming process repeated while inserting time intervals with the reaction process maintained, namely, the film forming process is carried out in pulse-like fashion under the operation of the reaction process.

In both cases, of course, a fixed film formation where a substrate remains stationary is made possible, and the film formation process can be turned ON/OFF in a pulse-like manner, so that a film formation can be carried out using a high power.

In the conventional structure in which separation of both the reaction process and the film forming process depends on only arrangement thereof, there may occur such a defect that the sputter target surface used for the film forming process is oxidized by the oxygen gas from the reactive gas source so that the film forming efficiency decreases. Although as its countermeasure, the film forming process is preferred to be carried out using a high power, in case of the conventional technology which may cause the interference between both the processes, the required power is higher than estimated and further by applying that higher power continuously, there occurs another problem that the film thickness is increased. For the reason, the parameter which should be considered when converting ultra thin film deposited on the substrate to metallic compound thin film becomes varied, which makes the control difficult.

Contrary to this, the present invention can achieve highly reliable film formation without generating a new problem of increased film thickness by turning ON/OFF the film forming process in pulse-like fashion as well as by preventing interference by the gas curtain.

As for the specific configuration of the thin film forming apparatus, as the reactive gas source, a reactive gas plasma generator such as a microwave plasma generator, an ion gun, or bombardment mechanism is utilized, and the main evacuation port and reactive gas exhaust port provided in the vicinity of this plasma generator are each provided with conductance adjusting valve. As a result, condition for continuing full-time supply of the reactive gas is realized.

That is, usage of such a conductance adjusting valve enables the flow rates of the sputter gas and reactive gas to be adjusted. When the thin film forming apparatus with the above-described structure is used, it is recognized that the sputter film forming rate is known to have correlation to be plotted onto a rate curve, in which the sputter gas flow rate and reactive gas flow rate are used as variables, comprised of three regions of high-, middle- and low-, namely, high-speed metallic film forming region, low-speed reactive film forming region and intermediate film forming region. In other words, the sputter film forming rate can be controlled in the three regions of high-, middle- and low-, depending on the flow rate of the reactive gas under a predetermined sputter gas flow rate, so that the aforementioned conductance adjusting valve performs the flow rate adjusting function.

Using such a thin film forming apparatus suppresses an influence on the film forming process by the reactive gas and deterioration of the target material even if the sputter gas and reactive gas are supplied continuously at the time of film formation. Thus, the film forming process and the reaction process can be switched quickly. Additionally, because the film forming process and the reactive process can be switched, film formation with a desired film thickness can be achieved by executing the film forming process by applying a pulse-like power, thereby realizing highly reliable and efficient film formation. Further, because the substrate can be fixed as described above, complication of the structure and cost increase accompanied by loading of the rotary substrate mechanism can be avoided. And further, the apparatus can be applied to in-line sputter film formation, which is difficult to be applied to the rotary substrate mechanism.

Under a condition in which the sputter gas and reactive gas are supplied continuously in the thin film forming apparatus at the time of film formation, by repeating the process of executing high-speed film formation of metallic ultra thin film by operating only the sputter film forming source between both the raw material supply sources and the reactive process of executing chemical reaction toward the film thickness direction of metallic ultra thin film by operating only the reactive gas source alternately according to any one of the above-described two methods, metallic compound film having an excellent film quality can be formed efficiently up to a desired film thickness.

In this alternate operation, one type makes both the process carried out alternately by starting any one process of the film forming process and the reaction process after the other process ends, and another type makes the film formation process repeated while inserting time intervals with the reaction process maintained. And any of the types can be carried out.

That is, because the process in which film formation of metallic thin film (ultra thin film) is dominant on the substrate and the process in which the reaction process (conversion to metallic compound thin film) is dominant are repeated alternately including a case where the reactive gas source is operated continuously with the sputter film forming source operated ON/OFF in pulse-like fashion, metallic compound film having an excellent film quality can be formed efficiently up to a desired film thickness.

That is, the control system of the thin film forming apparatus memorizes reactive gas flow rate under a predetermined sputter gas flow rate and sputter film forming rates comprised of three modes of high-, middle- and low-speeds, namely, high-speed metallic species film forming mode, low-speed compound species film forming mode and intermediate film forming mode, which are selected depending on the reactive gas flow rate, as reference data. At the time of the film formation under the predetermined sputter gas flow rate, the reactive gas flow rate and the sputter gas flow rate corresponding to the high-speed metallic species film forming mode are selected, and then both the gas flow rates (the reactive gas flow rate and the sputter gas flow rate) are controlled so as to maintain a ratio between the selected both gas flow rates. Consequently, decrease in the sputter film forming rate can be avoided and because a condition in which the film forming process is more dominant than the reaction process or a condition in which the reaction process is more dominant than the film forming process can be selected, these conditions in which any one process is more dominant than another is repeated alternately, thereby achieving film formation in a desired film thickness.

In this case, the growth in film thickness of the thin film in this film forming process is preferred to be limited to less than 20 Å in each film forming process. Consequently, chemical reaction in the following reaction process is penetrated to entire layer of the ultra thin film without being prevented by the film thickness of thin film deposited in the film forming process, thereby metallic compound film having an excellent film quality being generated.

When chemical compound film is formed on the substrate by means of the thin film forming apparatus of the present invention, the shielding effect against the reactive gas flow by sputter gas flow is obtained, so that the film forming process and the reaction process are progressed while suppressing the reactive gas from remaining in the vicinity of the target. By turning ON/OFF the supply of the sputter gas in the pulse-like fashion even in a condition in which the sputter gas and the reactive gas are supplied continuously, film formation is achieved at a high film formation rate specific to the metallic species film formation in the film forming process. In the reaction process, the reaction is performed entirely in the entire film thickness direction with an appropriate amount of the reactive gas. As a result, thin film of a desired film thickness can be formed efficiently without any unexpected increase in film thickness. Because the sputter source and the reactive gas source are separated by argon gas flow, a stationary substrate film formation system, excellent in terms of film forming stability, can be employed. Such a film formation system ensures a simple structure thereby leading to cost reduction.

Further, when the apparatus is applied to the in-line system, not only fixed type film formation but also passage type film formation can be carried out. By loading the apparatus to such a system, increase in film formation efficiency can be attained.

### BRIEF DESCRIPTION OF THE DRAWINGS

FIG. 1 is a schematic sectional view of a conventional carousel-type thin film forming apparatus;

FIG. 2 is a schematic sectional view of a conventional substrate rotation type thin film forming apparatus;

FIG. 3 is a schematic sectional view of a thin film forming apparatus according to the first embodiment of the present invention;

FIG. 4 is a graph showing the relation between oxygen gas flow rate and film forming rate under argon gas at a predetermined flow rate;

FIG. 5 is a schematic sectional view of the thin film forming apparatus according to the second embodiment of the present invention;

FIG. 6 is a schematic sectional view of the thin film forming apparatus according to the third embodiment of the present invention;

FIG. 7 is a schematic sectional view of the thin film forming apparatus according to the fourth embodiment of the present invention;

FIG. 8 is a schematic sectional view of the thin film forming apparatus according to the fifth embodiment of the present invention;

FIG. 9 is a schematic sectional view of the thin film forming apparatus according to the sixth embodiment of the present invention;

FIG. 10 is a process cycle diagram of film forming process and oxidizing process of the first example of the present invention;

FIG. 11 is a process cycle diagram of film forming process and oxidizing process of the third example of the present invention; and

FIG. 12 is a process cycle diagram of film forming process and oxidizing process of the fourth example of the present invention.

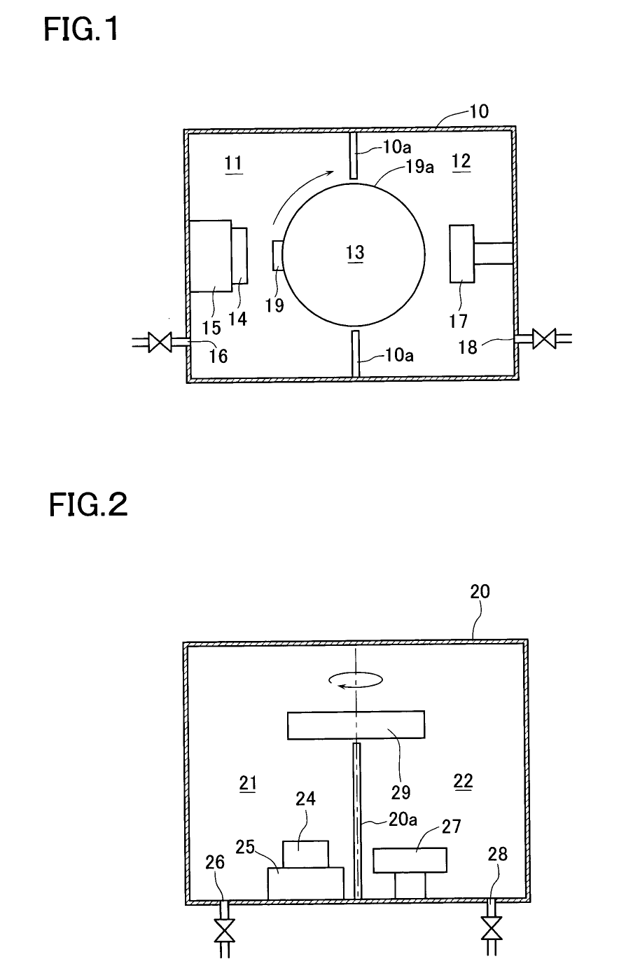

### DESCRITPTION OF THE PREFERRED EMBODIMENTS

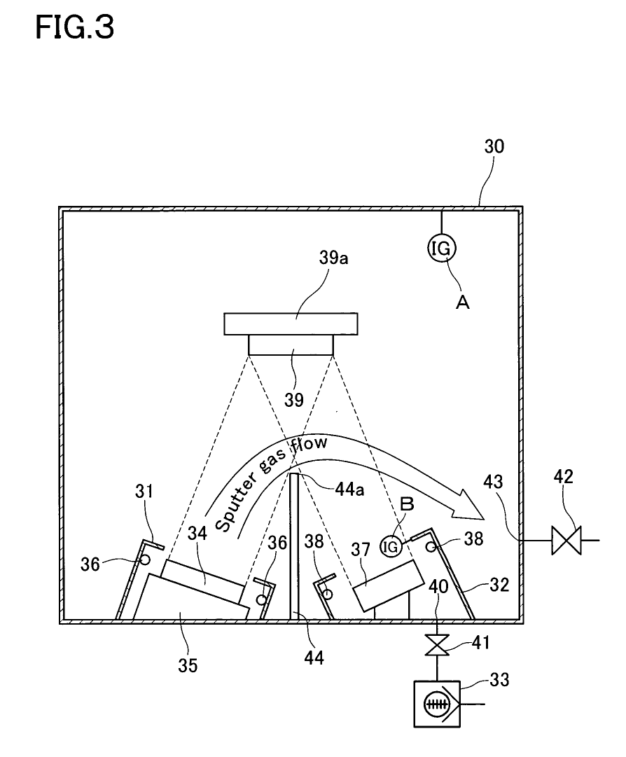

FIG. 3 is a schematic sectional view showing a thin film forming apparatus according to the first embodiment of the present invention. In FIG. 3, a cathode 35 having a Si target 34 formed integrally is provided in a region near a side face on the bottom of an apparatus chamber 30. Each of the target 34 and cathode 35 constructed integrally is covered with a protector plate 31 including a sputter gas introduction port 36 except in the particle emission direction. In the meantime, the cathode 35 is operated by a DC power supply.

A microwave gun 37 is provided in a region near other side face on the bottom of the apparatus chamber 30 and the microwave gun 37 is covered with a protector plate 32 including an oxygen gas introduction port 38 except in microwave irradiation direction. Further, an oxygen gas exhaust port 40 connected to a turbomolecular pump 33 is provided through the first conductance valve 41 on the bottom face covered with the protector plate 32 and the microwave gun 37 is included in a chimney structure.

A substrate 39 held by the substrate holder 39a is fixed in an upper region, and the target 34 and the microwave gun 37 are disposed so as to oppose the substrate 39. A main evacuation port 43 connected to a vacuum pump (not shown) is provided on a side face of the apparatus chamber 30 through the second conductance valve 42.

Both the first, second conductance valves 41, 42 are so constructed that their opening degrees can be controlled by a control system (not shown). Further, a partition wall 44 is provided in the center of the bottom of the apparatus chamber 30. The partition wall 44 is disposed not so as to protrude into a virtual sputter particle fly region formed by connecting extreme ends of the substrate 39 and target 34 opposing each other and a virtual microwave irradiation region formed by connecting extreme ends of the substrate 39 and microwave gun 37 opposing each other.

What is demanded at the time of film formation with the thin film forming apparatus 30 is that film is formed efficiently while avoiding deterioration of the surface of the target 34 due to flow-in of oxygen gas. The present invention utilizes shielding effect by argon gas indicated as sputter gas flow in FIG. 3.

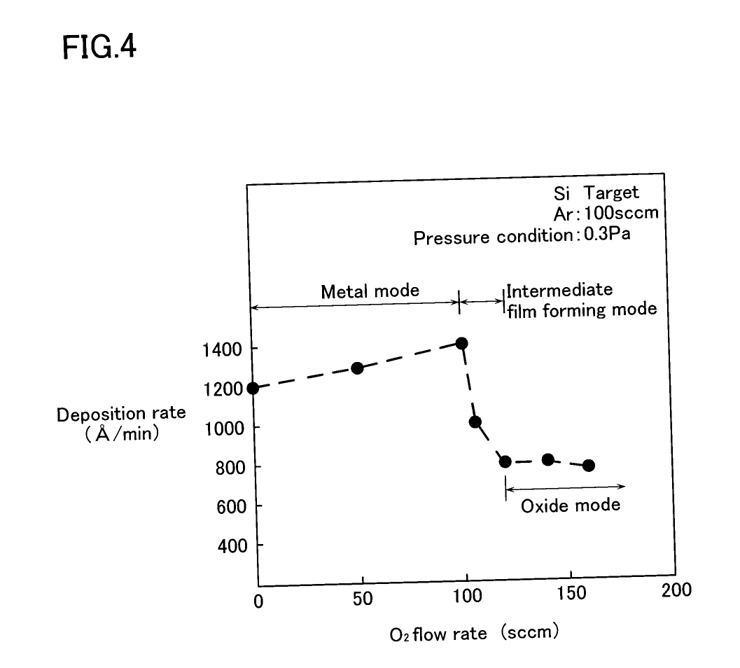

As described above, metallic ultra thin film is deposited according to the sputter method and by irradiating plasma or active species originating from reactive gas to this ultra thin film, this thin film is converted to metallic compound thin film and then, a process of the ultra thin film deposition and compound thin film conversion is repeated several times. When the oxygen gas flow rate is changed with the sputter gas fixed at a specified flow rate, the correlation between respective oxygen gas flow rate and film forming rate is shown in FIG. 4 (where it is assumed that argon is supplied at 100 sccm as the sputter gas and its film forming pressure is set to 0.3 Pa). A region in which the sputter film forming rate transits on a high level corresponds to metallic species film forming mode (Metal mode) which ensures a high film forming rate and a region in which the sputter film forming rate transits on a low level corresponds to oxide species film forming mode (Oxide mode) which ensures a low film forming rate in FIG. 4. Further, as transition section from the metallic species film forming mode to the oxide species film forming mode is named as an intermediate film forming mode, the sputter film forming rate can be classified to three modes of high-, middle- and low-.

Under the above-described metallic species film forming mode, flow-in of oxygen gas is prevented by shielding effect of argon gas and deposited species on the substrate is almost composed of metallic species, so that a high film forming rate peculiar to metallic species is maintained. On the other hand, under oxide species film forming mode, as oxygen gas flow rate increases, the shielding effect of argon gas decreases and reactive atmosphere containing oxygen gas is brought, so that the property of the target is deteriorated thereby inducing a decrease in film forming rate. Because deposited species almost composed of metallic species is chemically active under metallic species film forming mode, the species is abundant in reactivity even after deposited on the substrate before a quite large thickness is formed. Thus, by executing oxidizing reaction after the film thickness is formed to some extent, the deposited film is entirely oxidized in the direction of film thickness. Although metallic oxide film is formed as a resulting object, when formation of a thin film having a considerably large film thickness mentioned above is desired, this can be achieved by repeating ultra thin film deposition of metallic species and oxidizing reaction. The film forming rate of the metallic oxide film at this time is determined depending on a high film forming rate of metallic species under metallic species film forming mode and on oxidizing reaction rate for the deposited metallic species and the rate is much better than film forming rate under oxide species film forming mode. The apparatus of the present invention includes flow rate adjusting mechanism and deposited film reacting mechanism for sputter gas and reactive gas in order to execute efficient film formation.

When SiO₂ film is formed on the substrate 39 using the apparatus chamber 30 shown in FIG. 3, evacuation is carried out through a main evacuation port 43 so as to secure a predetermined pressure in the apparatus chamber 30. After that, a predetermined amount of argon gas is introduced through the sputter gas introduction port 36 while a specified amount of oxygen gas is introduced through the oxygen gas introduction port 38 so as to secure a predetermined pressure in the apparatus chamber 30. The flow rates of argon gas and oxygen gas at this time are adjusted by adjusting the second conductance valve 42 under a control system (not shown), so that, for example, oxygen gas of about 50 sccm is secured with respect to argon gas of 100 sccm under a constant pressure of 0.3 Pa. This ratio in the flow rate is set up so that the shielding effect of argon gas is exerted sufficiently so as to prevent the surface of the target 34 from being oxidized and a relatively high sputter film forming rate can be maintained. A tendency of the flow rate can be checked roughly with an ion gauge A (for argon gas) and an ion gauge B (for oxygen gas) provided within the apparatus of FIG. 3.

By applying a predetermined power (for example, 1 kW) to the Si target 34 through a DC power supply (not shown), the cathode 35 is brought into output waiting condition. On the other hand, by applying a predetermined power (for example, 0.5 kW) with a microwave power supply (not shown) connected to the microwave gun 37, irradiation of microwave plasma is brought into output waiting condition.

Under this condition, the film forming process by an operation of the cathode power supply and the oxidizing process (reactive process) by an operation of the microwave power supply are carried out by the above-mentioned control system repeatedly and alternately for a predetermined time. An argon gas flow path at a flow rate higher than that of oxygen gas is always established from the vicinity of the argon gas introduction port 36 toward the direction of the main evacuation port 43 all the time of the film forming process and the oxidizing process. Thus, oxygen gas introduced from the oxygen gas introduction port 38 is excited by microwave by an operation of the microwave power supply and evacuated from the main evacuation port 43 together with the aforementioned argon gas flow except those irradiated toward the substrate 39 as oxygen plasma. Therefore, even if oxygen gas is always introduced from the oxygen gas introduction port 38, the argon gas flow acts as an air curtain by exerting its shielding effect, so that oxygen gas is suppressed from remaining in the vicinity of the target 34. Therefore, changes in film forming rate and film quality due to oxidation of the target are prevented. Then, because deposition on the substrate 39 is maintained on the aforementioned metallic species film forming mode, a relatively high film forming rate is secured.

Further, in the thin film forming apparatus chamber 30 of the present invention, the oxygen gas exhaust port 40 is provided through the first conductance valve 41 as an auxiliary means in a space surrounded by the protector plate 32 so as to carry out differential exhaust through the oxygen gas exhaust port 40 and the main evacuation port 43, thereby exhaust of oxygen gas being adjusted. Consequently, oxidation of the target is prevented securely. This becomes advantageous in the case where the flow rate of sputter gas is small or sputter film formation is executed under a lower pressure. The control system for adjusting the first and second conductance valves 41, 42 stores oxygen gas flow rate under a predetermined argon gas flow rate and sputter film forming rates, which are classified to three modes (high, middle, low), namely, high-speed metallic species film forming mode, low-speed compound species film forming mode and intermediate film forming mode each depending on the oxygen gas flow rate, as reference data. At the time of film formation under the predetermined sputter gas flow rate, oxygen gas flow rate and argon gas flow rate are selected corresponding to high-speed metallic species film forming mode and then, these flow rates are controlled to maintain the ratio in the selected flow rate between oxygen gas and argon gas.

Although argon gas contained in sputter gas flow is also exhausted through the oxygen gas exhaust port 40, the argon gas flow path established from the vicinity of the argon gas introduction port 36 toward the direction of the main evacuation port 43 does not change largely because the evacuation capacity of the main evacuation port 43 is relatively superior. This condition is achieved by connecting a 12-inch cryopump (not shown) to the main evacuation port 43 and a 6-inch turbomolecular pump 33 to the oxygen gas exhaust port 40 in a condition of 100 sccm of the argon gas and 50 sccm of oxygen gas under a constant pressure of 0.3 Pa.

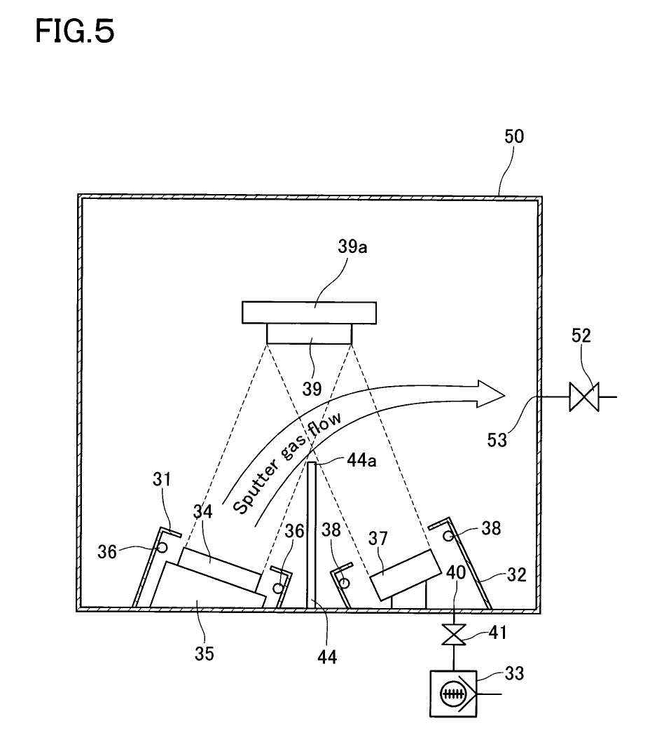

FIG. 5 is a schematic sectional view of the thin film forming apparatus according to the second embodiment of the present invention. This apparatus is different from the thin film forming apparatus shown in FIG. 3 in that the apparatus chamber 50 is constructed as a film forming chamber within an in-line type film forming apparatus. Such an in-line type film forming apparatus has been often used according to recent increase of processing processes and enlargement of the substrate, and in this embodiment, the substrate 39 is carried in a direction perpendicular to FIG. 5. Because this apparatus is so constructed that the substrate is stationary unlike the conventional example, the configuration thereof is simpler, so that it can be employed for the in-line system.

When SiO₂ film is formed on the substrate 39 in an apparatus chamber 50 constructed as shown in FIG. 5, the substrate 39 is brought into the chamber in the carrying direction (perpendicular to the drawing in FIG. 5). After the apparatus chamber 50 is set to a predetermined pressure condition, a predetermined flow rate of argon gas is introduced through the sputter gas introduction port 36 while a predetermined flow rate of oxygen gas is introduced through the oxygen gas introduction port 38 so as to keep the pressure in the film forming chamber at a constant condition. At this time, by adjusting the second conductance vale 52 with the control system (not shown), the shielding effect of argon gas is established like in case of the apparatus 30 shown in FIG. 3.

By applying a predetermined power to the Si target 34 from a DC power supply (not shown), the cathode 35 is set into output waiting condition and then, by applying a predetermined power to a microwave power supply (not shown) connected to the microwave gun 37, irradiation of microwave plasma is set to output waiting condition.

Under this condition, the film forming process by an operation of the cathode power supply and the oxidizing process by an operation of the microwave power supply are carried out repeatedly and alternately by the aforementioned control system. At this time, argon gas flow is established from the vicinity of the argon gas introduction port 36 toward the direction of the main evacuation port 53 all the time of both the processes. Oxygen gas introduced through the oxygen gas introduction port 38 except that excited with microwave by the microwave power supply and irradiated toward the substrate 39 as oxygen plasma, joins the argon gas flow and is evacuated via the main evacuation port 53.

That is, even if oxygen gas is always introduced through the oxygen gas introduction port 38, the argon gas flow acts as an air curtain for shielding from oxygen gas, thereby preventing changes in film forming rate and deterioration of film quality due to oxidation of the target. Consequently, like the thin film forming apparatus 30 shown in FIG. 3, a relatively high film forming rate is secured specific to the metallic species deposition mode. In the thin film forming apparatus chamber 50 also like the thin film forming apparatus chamber 30 shown in FIG. 3, the oxygen gas exhaust port 40 is provided as an auxiliary means within a space surrounded by the protector plate 32 and differential exhaust is carried out by adjusting exhaust conductance of the oxygen gas exhaust port 40 and the main evacuation port 53 appropriately; also, adjustment of oxygen gas is executed and oxidation of the target is prevented securely; additionally, the first and second conductance valves 41, 52 are adjusted by the control system.

Although according to the second embodiment, thin film is formed on a fixed substrate like the apparatus chamber 30 shown in FIG. 3, the film formation may be carried out while the substrate 39 is carried in the carrying direction (direction perpendicular to FIG. 5) of the in-line apparatus. This measure enables efficient film formation which can save the tact time, inherent of the in-line apparatus.

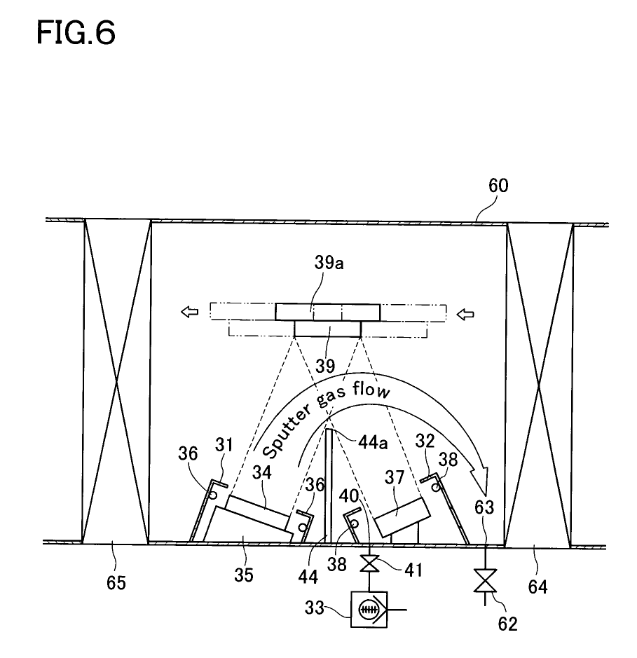

FIG. 6 shows a schematic sectional view of an in-line apparatus for passage film formation of this type as the third embodiment of a thin film forming apparatus of the present invention. This apparatus is different from the thin film forming apparatus chamber 50 shown in FIG. 5 in that a main evacuation port 63 for the apparatus chamber 60 is provided in a bottom face in the vicinity of a microwave gun 37. In such an in-line apparatus, a substrate 39 is carried in right and left directions on the drawing of FIG. 6.

When SiO₂ film is formed on the substrate 39 within a film forming apparatus chamber 60 constructed as shown in FIG. 6, the substrate 39 is carried in through partition valves 64, 65 so as to secure a predetermined pressure inside the apparatus chamber. After that, a predetermined flow rate of argon gas is introduced through the sputter gas introduction port 36 while a predetermined flow rate of oxygen gas is introduced through the oxygen gas introduction port 38 so as to keep a constant pressure inside the film forming apparatus chamber. By adjusting the second conductance valve 62 with a control system (not shown) at this time, the shielding effect of argon gas is established like the apparatus chamber 50 shown in FIG. 5.

By applying a predetermined power to the Si target 34 with a DC power supply (not shown), the cathode 35 is brought into output waiting condition, and by applying a predetermined power to a microwave power supply (not shown) connected to the microwave gun 37, irradiation of microwave plasma is brought into output waiting condition.

When a front end of the substrate 39 carried in the right/left direction in FIG. 6 invades into an overlapping area between a virtual sputter particle fly region made by the target 34 and a virtual microwave irradiation region made by a microwave gun 37, the film forming process by an operation of the cathode power supply and the oxidizing process by an operation of the microwave power supply are carried out repeatedly and alternately for each predetermined time. Then, when a rear end of the substrate 39 passes through the aforementioned overlapping area, both the processes end. In both the processes, argon gas flow is established from the vicinity of the argon gas introduction port 36 toward the direction of the main evacuation port 63. Oxygen gas introduced through the oxygen gas introduction port 38 except that excited by microwave by the operation of the microwave power supply and irradiated toward the substrate 39 joins the argon gas flow and is evacuated through the main evacuation port 63.

Consequently, changes in film forming rate and film quality due to oxidation of the target are prevented. As a result, a relatively high film forming rate specific to metallic species deposition mode is secured like in case of the thin film forming apparatus chamber 50 shown in FIG. 5. Further, oxidation of the target is prevented securely by adjusting the exhaust conductance of the oxygen gas exhaust port 40 and the main evacuation port 63 by a control system (not shown).

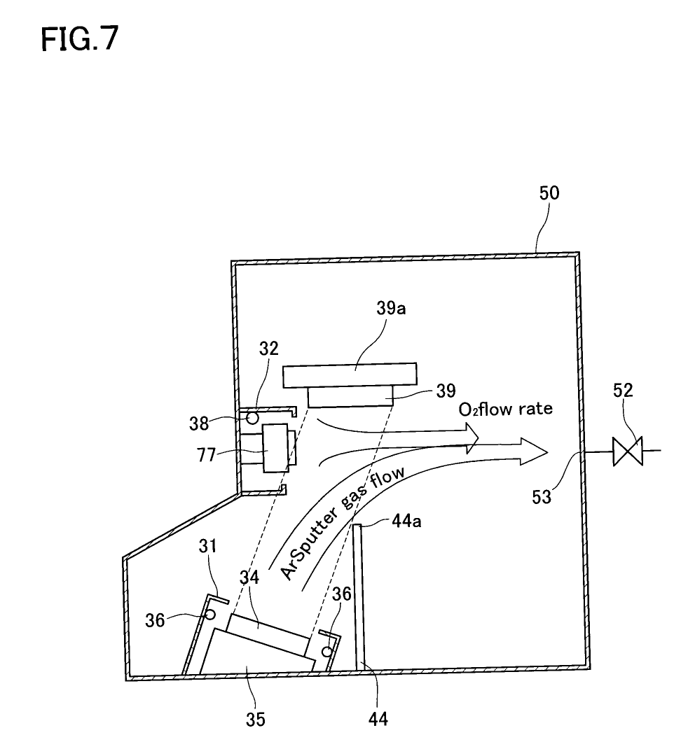

FIG. 7 shows the fourth embodiment of the present invention. This embodiment is different from the second embodiment shown in FIG. 5 in that a bombardment electrode 77 as an oxidizing source is provided in a side wall of the film forming chamber 50.

When SiO₂ film is formed on the substrate 39 within the film forming apparatus chamber 50 constructed as shown in FIG. 7, after the substrate 39 is carried in the carrying direction (direction perpendicular to the drawing of FIG. 7), the apparatus chamber is adjusted to a predetermined pressure condition and then, a predetermined flow rate of argon gas is introduced through the sputter gas introduction port 36. At the same time, a predetermined flow rate of oxygen gas is introduced through the oxygen gas introduction port 38 so as to secure a constant pressure inside the film forming apparatus chamber. Like the second embodiment in FIG. 5, the shielding effect by argon gas is established by adjusting the second conductance valve 52 by means of a control system (not shown) like the apparatus 30 shown in FIG. 3.

Then, by applying a predetermined power to the Si target 34 from the DC power supply, the cathode 35 is brought into output waiting condition and by applying a predetermined power from a RF power supply (not shown) connected to the bombardment electrode 77, the bombardment electrode 77 is set to output waiting condition.

Under this condition, the film forming process by the operation of the cathode power supply is repeated with a time interval with the oxidizing process by the operation of the RF power supply maintained continuously. At this time, argon gas flow is established from the vicinity of the argon gas introduction port 36 toward the main evacuation port 53 all the time of both the processes. Oxygen gas introduced through the oxygen gas introduction port 38 is excited continuously by the operation of the RF power supply so as to generate oxygen plasma on the surface of the bombardment electrode 77. Atomic oxygen or oxygen ion generated by plasma passes the front face of the substrate 39. The extremely thin metallic film (ultra thin film) deposited on the substrate 39 by an intermittent film forming process is oxidized layer by layer at the time of the intervals in film forming process, so that oxide film of a predetermined film thickness is obtained with a passage of time.

The gas to be introduced from the reactive gas introduction port 38 may contain O₃ gas.

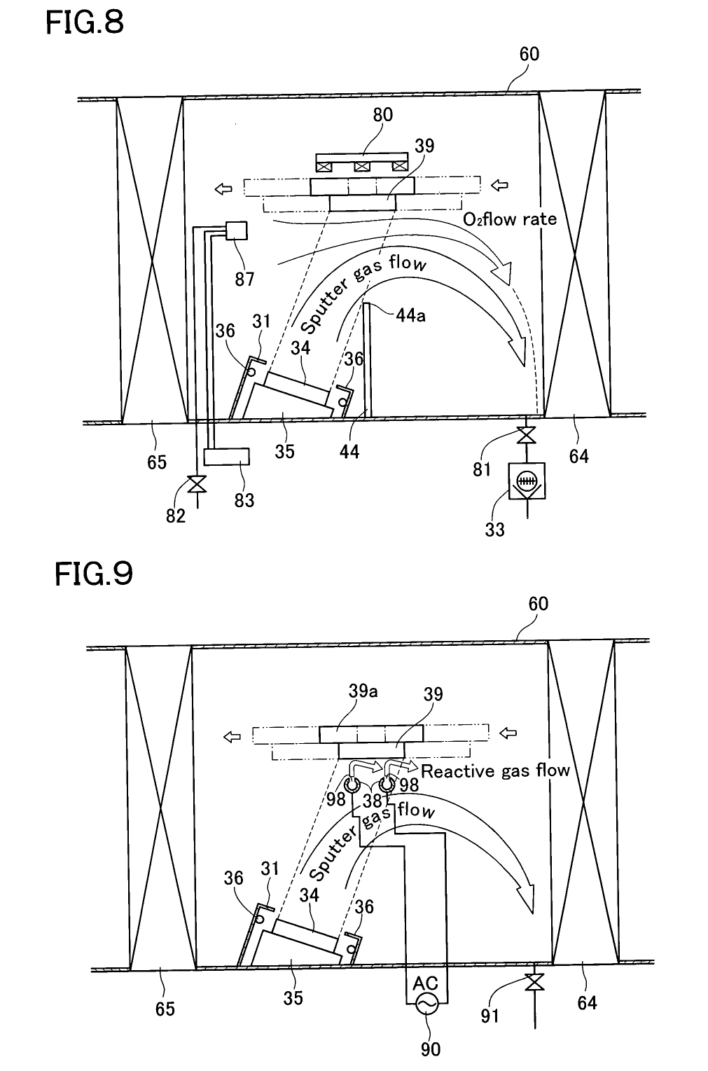

FIG. 8 shows the fifth embodiment of the present invention. This embodiment is different from the third embodiment shown in FIG. 6 in that an ion gun 87 connected to a microwave power supply 83 (not shown) is provided near the substrate 39 as an oxidizing source; the ion gun 87 is capable of supplying O₂ gas through the reactive gas introduction valve 82; a magnetic field circuit 80 for generating magnetic field is provided on the back of the substrate 39 or the like.

When SiO₂ film is formed on the substrate 39 within the film forming apparatus chamber 60 constructed as shown in FIG. 8, the substrate 39 is carried into the chamber through the partition valves 64, 65. After the apparatus chamber is set to a predetermined pressure condition, a predetermined flow rate of argon gas is introduced through the sputter gas introduction port 36. By operating the oxygen gas introduction valve 82 to introduce oxygen gas of a predetermined flow rate, the pressure of the film forming apparatus chamber is adjusted to a constant level. The condition until the shielding effect is established by argon gas by adjusting the second conductance valve 81 by means of a control system (not shown) is the same as the third embodiment shown in FIG. 6.

By applying a predetermined power to the Si target 34 from a DC power supply (not shown), the cathode 35 is brought into output waiting condition and by applying a predetermined power to the microwave power supply 83 connected to an ion gun 87, irradiation of the ion gun 87 is brought into output waiting condition.

When a front end of the substrate 39 carried in the right/left direction invades into an overlapping area between the virtual sputter particle fly region made by the target 34 and the virtual ion gun irradiation region made by the ion gun 87, ECR oxidizing process by the operation of the microwave power supply 83 and the ion gun 87 is maintained continuously while the film forming process is repeated with a time interval. At this time, argon gas flow is established from the vicinity of the argon gas introduction port 36 toward the main 25 evacuation port 53 all the time of both the processes. Oxygen gas introduced through the oxygen gas introduction valve 82 is excited continuously by the operation of the microwave power supply 83 and the ion gun 87 so as to generate oxygen ECR plasma. Atomic oxygen or oxygen ion generated by the ECR plasma passes the front face of the substrate 39. The extremely thin metallic film (ultra thin film) deposited on the substrate 39 by an intermittent film forming process is oxidized layer by layer at the time of the intervals in film forming process, so that oxide film of a predetermined thickness is obtained with a passage of time.

FIG. 9 shows the sixth embodiment of the present invention. This embodiment is different from the fifth embodiment in that a pair of O₂ gas nozzles connected to an AC power supply 90 outside the apparatus chamber is provided near the substrate 39 as an oxidizing source. Gas holes are made to spout gas against the face of the substrate 39 and actual application of AC power is conducted via two metal pipes 38 provided with gas nozzles 98.

Like the fifth embodiment shown in FIG. 8, when a front end of the substrate 39 carried in the right/left direction enters into the virtual sputter particle fly region made by the target 34, with the plasma oxidizing process by the operation of the AC power supply 90 maintained continuously, the film forming process by the operation of the cathode power supply is repeated intermittently with a time interval. At this time, argon gas flow is established from the vicinity of the argon gas introduction port 36 toward the main evacuation valve 91 all the time of both the processes. Oxygen gas introduced through the gas nozzle 98 is excited continuously by the operation of the AC power supply 90 so as to generate oxygen plasma and then, atomic oxygen or oxygen ion generated by plasma passes the front face of the substrate 39. The extremely thin metallic film (ultra thin film) deposited on the substrate 39 by an intermittent film forming process is oxidized layer by layer at the time of the intervals in film forming process, so that oxide film of a predetermined film thickness is obtained with a passage of time.

Although according to these embodiments, the thin film to be formed is SiO₂ film, the present invention is not restricted to this example, and needless to say, it is permissible to form TiO₂ film or Ta₂O₅ film instead thereof. In these cases, Ti or Ta is used as material of the target 34.

Although according to these embodiments, oxide film is formed, the present invention is not limited to this example and may be applied to formation of nitride film.

### EXAMPLE 1

In the apparatus 30 shown in FIG. 3, a Si cathode having a diameter of 4 inch was used as the target 34 and the cathode 35. The flow rate of argon gas introduced from the sputter gas introduction port 36 was adjusted to 100 sccm under an instruction of a control system based on memorized reference data and the flow rate of oxygen gas supplied from the oxygen gas introduction port 38 was adjusted to 50 sccm. Then, by 25 applying a power of 1 kW to the Si cathode 35 from a DC power supply, the cathode is brought into output waiting condition, and by applying a power of 0.5 kW from a microwave power supply, irradiation of microwave plasma is brought into output waiting condition.

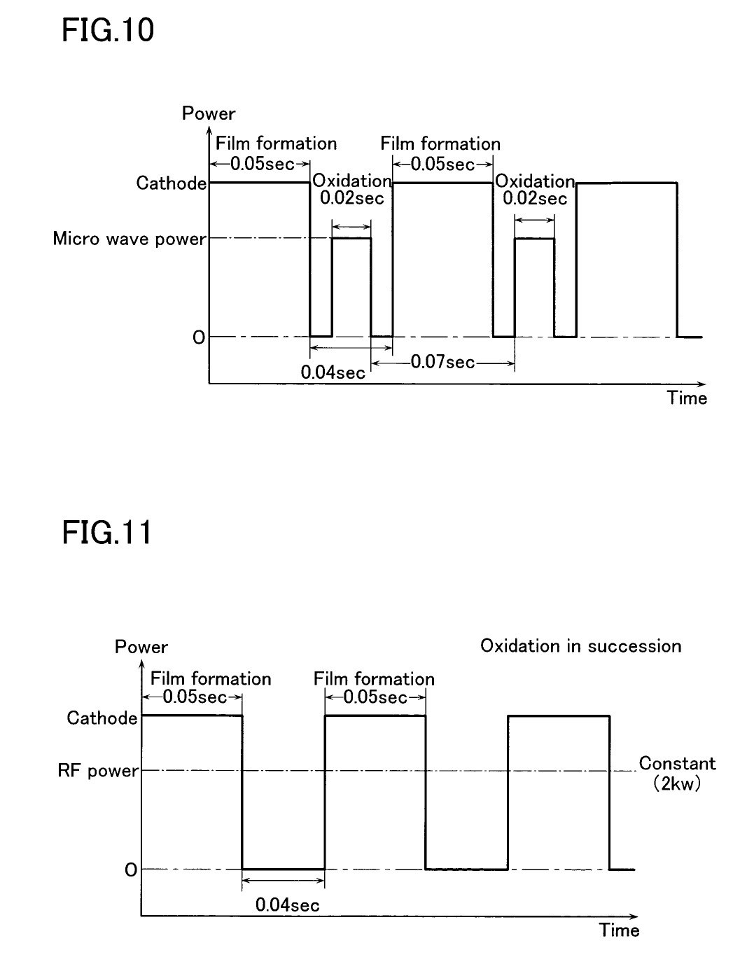

Under the above-mentioned control system, the film forming process by the operation of the cathode power supply was so set that ON took 0.05 seconds while OFF took 0.04 seconds. The oxidizing process by the operation of the microwave power supply was so set that ON took 0.02 seconds while OFF took 0.07 seconds. The both processes were repeated alternately (see FIG. 10). At this time, the film thickness of the Si metallic film grew by 2 Å at one film forming process. After both the processes were repeated for 60 minutes, the film thickness grew to 12 μm.

As a result of investigation of the thin film, it was made evident that this had an amorphous film structure. Further, as a result of measuring optical property of this thin film in an infrared region, it was evident that this film was an excellent optical thin film (SiO₂ film) having a refractivity of 1.46 and extinction coefficient of 3×10⁻⁴.

### COMPARATIVE EXAMPLE 1

The thin film (SiO₂ film) was formed in the same way except that the flow rate of oxygen gas from the oxygen gas introduction port 38 was changed.

Regarding each oxygen gas flow rate at this time, Table 1 indicates pressure values measured at ion gauge places A and B within the apparatus chamber 30 shown in FIG. 3.

TABLE 1

| Ar flow rate | O₂ flow rate | I/G A | I/G B |
|---|---|---|---|
| (sccm) | (sccm) | (Pa) | (Pa) |
| 100 | 0 | 0.28 | 0.1 |
| 100 | 25 | 0.29 | 0.2 |
| 100 | 50 | 0.30 | 0.3 |
| 100 | 100 | 0.40 | 0.5 |
| 100 | 150 | 0.60 | 0.8 |

Table 1 indicates that if oxygen gas flow rate is less than 50 sccm, a sufficient differential pressure between the ion gauge installation places A and B is secured. This indicates that argon gas flow is established from the vicinity of the argon gas introduction port 36 toward the main evacuation port 43, thereby exerting a sufficient shielding effect of oxygen gas by argon.

By considering with example 1 and comparative example 1 by comparison, it is estimated that according to film forming method using a thin film forming apparatus of the present invention, the shielding effect of oxygen gas by argon gas flow is exerted so that thin film is deposited by the surface of a metallic target and oxidizing reaction penetrates into this deposited film thereby consequently forming oxide film. That is, because film formation is progressed with a high film forming rate peculiar to metallic film formation, it can be said that the method of the present invention enables a relatively high-speed film formation.

### EXAMPLE 2

In the apparatus chamber 50 shown in FIG. 5, a 5×16-inch Si cathode was adopted for the target 34 and the cathode 35 and the sputter film forming apparatus chamber 50 was kept at a constant pressure of 0.3 Pa. Under an instruction from the control system based on memorized reference data, argon gas flow rate from the sputter gas introduction port 36 was adjusted to 100 sccm while oxygen gas from the oxygen gas introduction port 38 (containing 10 volume % 03 gas) was adjusted to 50 sccm. By applying a power of 5 kW from the DC power supply to the Si cathode 35, the cathode was brought into output waiting condition and by applying a power of 2.0 kW from a microwave power supply, irradiation of microwave plasma was brought into output waiting condition.

The film forming process by the operation of the cathode power supply was set up by the aforementioned control system such that ON continues for 0.05 seconds while OFF continues for 0.04 seconds. Then, the oxidizing process by the operation of the microwave power supply was set up such that ON continued for 0.02 seconds while OFF continued for 0.07 seconds. By repeating both the processes (see FIG. 10) alternately, the Si metallic film grew in film thickness by 2 Å at one film forming process like example 1. Under this condition, film was formed while a transportation carrier (not shown) for the substrate 39 was carried at a speed of 1 m/min. As a result of precision investigation on this thin film, it was made evident that this film had an amorphous film structure. Further, as a result of measuring its optical property of this thin film in the infrared region, it was clarified that this film was an excellent optical thin film (SiO₂ film) having a refractivity of 1.46 and an extinction coefficient of 3×10⁻⁴.

### EXAMPLE 3

In the apparatus chamber 50 shown in FIG. 7, a 5×16-inch Si cathode was adopted for the target 34 and the cathode 35 and the sputter film forming apparatus chamber 50 was kept at a constant pressure of 0.3 Pa. Under an instruction from the control system based on memorized reference data, argon gas flow rate from the sputter gas introduction port 36 was adjusted to 100 sccm while oxygen gas from the oxygen gas introduction port 38 was adjusted to 50 sccm. By applying a power of 5 kW from a DC power supply (not shown) to the Si cathode 35, the cathode was brought into output waiting condition and by applying a power of 2.0 kW from an RF power supply, the bombardment electrode 77 was brought into output waiting condition.

The bombardment electrode 77 was operated continuously by applying a predetermined power (2 kW) from the RF power supply under the above-described control system. Then, the film forming process by the operation of the cathode power supply was set up such that ON continued for 0.05 seconds while OFF (interval) continued for 0.04 seconds. By repeating this cycle (see FIG. 11), the Si metallic film grew in film thickness by 2 Å at one film forming process like example 1. As a result of measuring its optical property of its compound film in an infrared region, that finally obtained film was an excellent optical film (SiO₂ film) having a refractivity of 1.46 and an extinction coefficient of 7×10⁻⁴.

### EXAMPLE 4

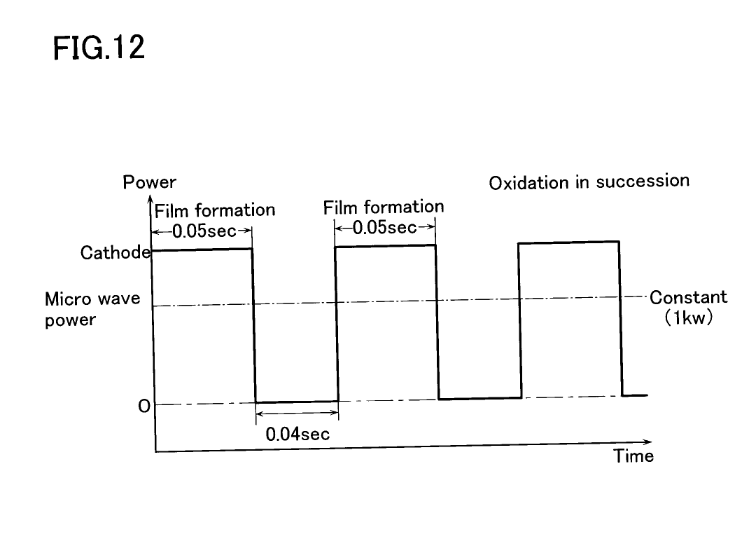

After the cathode 35 and the ion gun 87 were brought into output waiting condition in the apparatus chamber 60 shown in FIG. 8 as described above, the ion gun 87 was operated continuously by applying a predetermined power (2 kW) with a microwave power supply 83 under the control system. Then, the film forming process by the operation of the cathode power supply of 1 kW was set up such that ON continued for 0.05 seconds while OFF (interval) continued for 0.04 seconds. By repeating this cycle (see FIG. 12), the Si metallic film grew by 2 Å in film thickness at one film forming process. As a result of measuring its optical property of its compound film in an infrared region, that finally obtained film was an excellent optical film (SiO₂ film) having a refractivity of 1.46 and an extinction coefficient of 2×10⁻⁴.

### EXAMPLE 5

In the apparatus chamber 60 shown in FIG. 9, oxygen plasma was generated by applying a predetermined power to a pair of metallic pipes 38 from an AC power supply of 10 kHz under the above-described control system. Then, the film forming process by the operation of the cathode power supply of 2 kW was set up such that ON continued for 0.05 seconds while OFF (interval) continued for 0.04 seconds. By repeating this cycle, the Si metallic film grew 3 Å in film thickness at one film forming process. As a result of measuring its optical property of its compound film in an infrared region, the finally obtained film was an excellent optical thin film (SiO₂ film) having a refractivity of 1.46 and an extinction coefficient of 6×10⁻⁴. In the meantime, by continuing this film forming process for 40 minutes, the film thickness grew to 12 μm.

### COMPARATIVE EXAMPLE 2

By changing the ON/OFF time of the cathode power supply (ON for 0.05 seconds/OFF for 0.04 seconds) in example 5 to conduct setting so as to be always ON, the resulting compound film had a large absorption so that a desired transparency could not be obtained. This reason is that because metal sputter particles were continuously deposited to the substrate, which was different in example 5, where the film forming process was intermittently interposed, entire oxidation could not follow.

### COMPARATIVE EXAMPLE 3

The ON/OFF time of the cathode power supply in example 5 (ON for 0.05 seconds/OFF for 0.04 seconds) was changed so that the ON time was 0.5 seconds. As a result of growing the Si metallic film by 30 Å in film thickness at one film forming process, a film having a refractivity of 1.52 and an extinction coefficient of 8×10⁻² was obtained thereby indicating a high absorption. This reason is that because of much more metallic sputter particles than that of example 5, oxidation could not follow up so that the SiO₂ film and the metallic Si film were mixed up.

### COMPARATIVE EXAMPLE 4

By changing a power applied on the cathode power supply (2 kW) in example 5, the cathode power was changed to 0.5 kW. Further, the ON/OFF time of the cathode power supply (ON for 0.05 seconds/OFF for 0.04 seconds) was changed such that ON continued for 0.2 seconds while OFF continued for 0.04 seconds. Further, film formation was continued for 40 minutes so as to grow the Si metallic film by 3 Å in film thickness at one film forming process. As a result of measuring its optical property of the compound film in an infrared region, that finally obtained optical film (SiO₂ film) was a transparent optical film having a refractivity of 1.46 and an extinction coefficient of 4×10⁻⁴.

However, the film grew to 5.0 μm in film thickness and it was made evident that the film forming rate was extremely low. Consequently, it comes that some amount of oxygen gas is left on a sputter target to some extent. When sputter power is high, a strong sputter with argon occurs even if the surface of the target is very thinly oxidized. Thus, oxide film always continues to be removed, thereby achieving metal-mode film formation. However, when such power is low, the sputter is carried out with so-called oxide mode because the surface of the target is kept oxidized. As a result, the obtained thin film is a transparent SiO₂ film, however, such a disadvantage as reduction of film forming rate is accompanied.

### EXAMPLE 6

By changing a power applied on the cathode power supply (2 kW) in example 5, the cathode power was changed to 4.0 kW. Further, the ON/OFF time of the cathode power supply (ON for 0.05 seconds/OFF for 0.04 seconds) was changed such that ON continued for 0.025 seconds while OFF continued for 0.065 seconds. Further, film formation was continued for 40 minutes so as to grow the Si metallic film by 3 Å in film thickness at one film forming process. As a result of measuring its optical property of the compound film in an infrared region, that finally obtained optical film (SiO₂ film) was a transparent optical film having a refractivity of 1.46 and an extinction coefficient of 5×10⁻⁴. In the meantime, such film forming process was executed for 40 minutes so that the film grew to 24 μm in thickness.

This result indicates that the film forming rate was increased as twice as that in Example 5 because the film thickness at one film forming process was 3 Å which meant that a sufficient oxidation could be achieved and additionally the ON time (0.05 seconds) of one process was half the case of example 5 (0.025 seconds), which indicated that film formation in 3 Å each time was achieved.

The present invention is important in the optical thin film field requiring film formation at a high speed.

### DESCRIPTION OF REFERENCE NUMERALS

10, 20, 30, 50 and 60: Thin film forming apparatus

| 14, 24, and 34: | Target |
|---|---|
| 15, 25 and 35: | Sputter cathode |
| 16, 26 and 36: | Sputter gas introduction port |
| 17, 27 and 37: | Microwave exciting plasma generator |
| | (Microwave gun) |
| 18, 28 and 38: | Reactive gas introduction port |
| 19, 29 and 39: | Substrate |
| 40: | Reactive gas exhaust port |
| 41: | First conductance valve (Conductance |
| | adjusting valve) |
| 42, 52, 62, 81 and 91: | Second conductance valve (Conductance |
| | adjusting valve) |
| 43, 53 and 63: | Main evacuation port |
| 77: | Bombardment electrode |
| 82: | Oxygen gas introduction valve |
| 83: | Microwave power supply |
| 87: | Ion gun |

What is claimed is:

1. A thin film forming apparatus containing raw material supply sources, namely a sputter film forming source and a reactive gas supply source in a same vacuum chamber such that both the sources oppose a substrate, wherein a main evacuation port for evacuating the vacuum chamber is disposed closer to the reactive gas supply source between both the sources, the thin film forming apparatus further including a control system which executes a reaction process of operating the reactive gas supply source provided with a reactive gas introduction port and a reactive gas exhaust port and a film forming process of operating the sputter film forming source provided with a sputter gas introduction port.

2. The thin film forming apparatus according to claim 1 wherein the control system executes both the processes alternately by starting any one of the reaction process and the film forming process after the other process ends.

3. The thin film forming apparatus according to claim 1 wherein with the reaction process maintained, the control apparatus repeats the film forming process with a time interval.

4. The thin film forming apparatus according to claim 1 wherein the reactive gas source is constituted of a reactive gas plasma generator and the main evacuation port and the reactive gas exhaust port disposed near the plasma generator are provided each with conductance adjusting valve.

5. A thin film forming method using the thin film forming apparatus according to claim 2 wherein with sputter gas and reactive gas supplied continuously at the time of film formation, of both the raw material supplying sources, the film forming process to be carried out by operating the sputter film forming source and the reaction process to be carried out by operating the reactive gas source are executed alternately by starting any one process thereof after the other process ends.

6. A thin film forming method using the thin film forming apparatus according to claim 3 wherein with the film forming process to be carried out by operating the sputter film forming source maintained, the reaction process to be carried out by operating the reactive gas source is executed repeatedly with a time interval.

7. A thin film forming method wherein the control system of the thin film forming apparatus according to claim 1 memorizes reactive gas flow rate under a predetermined sputter gas flow rate and sputter film forming rates comprised of three modes of high-, middle- and low-speeds, namely, high-speed metallic species film forming mode, low-speed compound species film forming mode and intermediate film forming mode, which are selected depending on the reactive gas flow rate, as reference data and at the time of the film formation under the predetermined sputter gas flow rate, the reactive gas flow rate and the sputter gas flow rate corresponding to the high-speed metallic species film forming modes are selected and then both the gas flow rates are controlled so as to maintain a ratio between the selected both gas flow rates, namely reactive gas flow rate and sputter gas flow rate, thereby making it possible to select a condition in which the film forming process is more dominant than the reaction process or to select a condition in which the reaction process is more dominant than the film forming process.

8. The thin film forming method according to claim 5 wherein the growth of thin film thickness in the film forming process is less than 20 Å in each film forming process.

9. The thin film forming method according to claim 6 wherein the growth of thin film thickness in the film forming process is less than 20 Å in each film forming process.

10. The thin film forming method according to claim 7 wherein the growth of thin film thickness in the film forming process is less than 20 Å in each film forming process.
